(19) United States
(12) Patent Application Publication
(10) Pub. No.: US 2011/0133175 A1
(43) Pub. Date: Jun. 9, 2011

(54) HIGH-PERFORMANCE HETEROSTRUCTURE LIGHT EMITTING DEVICES AND METHODS

(76) Inventors: Yungryel Ryu, Columbia, MO (US); Tae-Seok Lee, Columbia, MO (US); Henry W. White, Columbia, MO (US)

(21) Appl. No.: 12/811,943

(22) PCT Filed: Jan. 6, 2009
(86) PCT No.: PCT/US2009/030186

§ 371 Date: Nov. 29, 2010

Related U.S. Application Data
(60) Provisional application No. 61/019,817, filed on Jan. 8, 2008.

(51) Int. Cl. H01L 33/28; H01L 33/32

(52) U.S. Cl. 257/43; 438/29; 257/E33.02; 257/E33.023

(57) ABSTRACT

A layered heterostructure light emitting device comprises at least a substrate, an n-type gallium nitride-based semi-conductor cladding layer region, a p-type gallium nitride-based semiconductor cladding layer region, a p-type zinc oxide-based hole injection layer region, and an ohmic contact layer region. Alternatively, the device may also comprise a capping layer region, or may also comprise a reflective layer region and a protective capping layer region. The device may also comprise one or more buried insertion layers adjacent to the ohmic contact layer region. The ohmic contact layer region may be comprised of materials such as indium tin oxide, gallium tin oxide, or indium tin oxide material. An n-electrode pad is formed that is in electrical contact with the n-type gallium nitride based cladding layer region. A p-type pad is formed that is in electrical contact with the p-type region.

### CROSS-REFERENCE TO RELATED APPLICATIONS; INCORPORATION BY REFERENCE

This application for patent claims the priority benefit of U.S. Provisional Application for Patent Ser. No. 61/019817 filed Jan. 8, 2008 (Attorney Docket MOXT-108-PR), which is incorporated herein by reference. Also incorporated by reference herein are the following commonly owned patent applications:

PCT/US03/27143 filed Aug. 27, 2003 (MOXT-002-PCT);

PCT/US06/02534 filed Jan. 25, 2006 (MOXT-003-PCT);

PCT/US06/11619 filed Mar. 28, 2006 (MOXT-004-PCT);

PCT/US05/43821 filed Dec. 6, 2005 (MOXT-005-PCT);

PCT/US07/77003 filed Aug. 28, 2007 (MOXT-106-PCT); and

PCT/US08/81556 filed Oct. 29, 2008 (MOXT-107-PCT).

### FIELD OF THE INVENTION

The present invention relates generally to semiconductor heterostructure light emitting devices, and more particularly, to improvements in the power efficiency and performance of light emitting devices comprising zinc oxide-based and gallium nitride-based materials, as well as methods related to such devices.

### BACKGROUND OF THE INVENTION

It is well known that a light emitting diode (LED) device can be used to convert electrical energy to light energy. A conventional LED has a layered structure comprising at least an n-type semiconductor layer region, an active semiconductor layer region, and a p-type semiconductor layer region. This structure can be fabricated by means of several different semiconductor material deposition methods. Wide bandgap semiconductor materials that are gallium nitride-based, such as gallium nitride (GaN), indium gallium nitride (InGaN), aluminum gallium nitride (AlGaN), indium aluminum gallium nitride (InAlGaN), and wide bandgap semiconductor materials that are zinc oxide-based such as zinc oxide (ZnO), and beryllium zinc oxide (BeZnO), have been used to obtain light emission in the ultraviolet (UV) and visible spectral regions.

A laser diode (LD) is a light emitting device wherein the spectral output features are more specific, including, but not limited to, one or more spectrally narrow emission lines.

Electrical charges flow between electrical contact regions through the active semiconductor layer region in a conventional light emitting device. Electrical carriers of both n-type and p-type conductivity exist in the active layer region, and produce light by combination processes. The electrical carriers in the light emitting structure move in response to an electric field generated between two electrodes, and in response to a voltage difference applied to the two electrodes. Each electrode forms an electrical contact to a semiconductor layer region. The active layer region is comprised of one or more layers, and contains both n-type and p-type carriers. If the concentration of p-type carriers in the active layer region is lowered, then the light emitting efficiency of the device will be reduced, thereby reducing the power efficiency and performance of the device. Increasing the number of p-type carriers in the active layer region can increase the power efficiency and performance of a light emitting device. A light emitting device operates at higher power efficiency and performance when the number of p-type carriers in the active layer region is sufficient to give a high rate for conversion of p-type and n-type electrical carriers to light. Enhancements in the ability of a light emitting device to operate at high power efficiency and performance increase its functionality and increase the number of potential applications for which it can be employed.

Improving the electrical contact to a light emitting device can improve the efficiency and performance of the device. There exist various ohmic contact layer structures and various materials intended to form improved ohmic contact layers for decreasing the electrical contact resistance for an electrode on a layer in a light emitting device. For example, an ohmic contact layer may comprise a layer, or more than one layer, selected from the list including, but not limited to, indium tin oxide, gallium zinc oxide, and indium zinc oxide.

There also exist various types of electrode structures and various materials for forming improved electrodes for decreasing the electrical contact resistance for an electrode on a layer in a light emitting device. For example, an electrode may employ a metallic element or a combination of metallic elements, a conducting layer, or some combination thereof. Alternatively, a light emitting structure may also employ an electrically conducting layer comprised of one or more elements or compounds to increase the effective area of the electrode, thereby improving electrical contact. Alternatively, a light emitting structure may employ a thin, buried insertion layer comprised of one or more metallic elements or compounds that improves electrical contact to an ohmic contact layer.

It is generally more difficult to form p-type carriers (holes) than n-type carriers (electrons) in an inorganic semiconductor material.

In light emitting devices comprised of wide bandgap materials that are gallium nitride-based, such as gallium nitride (GaN), indium gallium nitride (InGaN), aluminum gallium nitride (AlGaN), and indium aluminum gallium nitride (InAlGaN) are limited in efficiency and performance due to the fact that in the active layer region the concentration of p-type carriers (holes) is lower than the concentration of n-type carriers.

It would be desirable to provide improvements in the overall operating efficiency of such devices.

Methods of attaining desirable improvements in accordance with the present invention will be discussed below.

Various layered structures for LEDs are discussed or disclosed in the following U.S. patents, which are incorporated herein by reference as if set forth herein in their entireties:

US 2003/0209723 A1 Sakai

US 2005/0077537 A1 Seong et al.

US 2005/0082557 A1 Seong et al.

US 2007/0111354 A1 Seong et al.

By way of further background, it is noted that wide bandgap semiconductor materials are useful for device operation at high temperatures. Zinc oxide is a wide bandgap material, and it also possesses good radiation resistance properties. Wide bandgap semiconductor films of zinc oxide are now available in both n-type and p-type carrier types that have properties sufficient for fabrication of semiconductor devices. In addition, wide bandgap semiconductor alloy materials are useful for device operation at high temperatures. Beryllium zinc oxide is a wide bandgap material, and it also possesses good radiation resistance properties. Wide bandgap semiconductor films of beryllium zinc oxide are now available in both n-type and p-type carrier types that have properties sufficient for fabrication of semiconductor devices.

In addition, U.S. Pat. No. 6,291,085 to White et al. discloses a p-type doped zinc oxide film, wherein the film could be incorporated into semiconductor devices including, but not limited to, LEDs and LDs.

U.S. Pat. No. 6,342,313 to White et al. discloses a p-type doped metal oxide film having a net acceptor concentration of at least about 10¹⁵ acceptors/cm³, wherein:

(1) the film is an oxide compound of an element selected from the groups consisting of Group 2 (beryllium, magnesium, calcium, strontium, barium and radium), Group 12 (zinc, cadmium and mercury), Group 2 and 12, and Group 12 and Group 16 (oxygen, sulfur, selenium, tellurium and polonium) elements, and

(2) wherein the p-type dopant is an element selected from the groups consisting of Group 1 (hydrogen, lithium, sodium, potassium, rubidium, cesium and francium), Group 11 (copper, silver and gold), Group 5 (vanadium, niobium and tantalum) and Group 15 (nitrogen, phosphorus, arsenic, antimony and bismuth) elements.

U.S. Pat. No. 6,410,162 to White et al. discloses a p-type doped zinc oxide film, wherein the p-type dopant is selected from Group 1, 11, 5 and 15 elements, and wherein the film is incorporated into a semiconductor device including LEDs and LDs. This patent also disclosed a p-type doped zinc oxide film, wherein the p-type dopant is selected from Group 1, 11, 5 and 15 elements, and wherein the film is incorporated into a semiconductor device as a substrate material for lattice matching to materials in the device.

PCT Application Ser. No. PCT/US06/02534 to Ryu et al. discloses (beryllium, zinc, and oxygen) alloys with energy band gaps that are higher than the energy band gap of zinc oxide and (zinc, cadmium, selenium, sulfur and oxygen) alloys with energy band gap that are lower than the energy band gap of zinc oxide. They also disclose p-type doped (beryllium, zinc, and oxygen) alloys; namely, BeZnO alloys, and (zinc, cadmium, selenium, and oxygen) alloys; namely, ZnCdSeO alloys, having net acceptor concentration of at least about 10¹⁵ acceptors/cm³, wherein:

(1) the p-type dopant is an element selected from the groups consisting of Group 1 (hydrogen, lithium, sodium, potassium, rubidium, cesium and francium), Group 11 (copper, silver and gold), Group 5 (vanadium, niobium and tantalum) and Group 15 (nitrogen, phosphorus, arsenic, antimony and bismuth) elements,

(2) the p-type dopant comprises arsenic; and

(3) alloy layers are incorporated into a semiconductor device including, but not limited to LEDs and LDs.

Each and every one of the above-referenced documents is incorporated by reference herein, and made a part of this application for patent, as if set forth in its entirety herein.

Those skilled in the art will appreciate that a light emitting device comprising a heterostructure can improve the power efficiency and performance of the device. Heterostructure light emitting devices that can operate at high efficiency and with high performance are desirable for use in many commercial and military sectors, including, but not limited to, areas such as general lighting, white light sources, LEDs, LDs, communication networks, and sensors.

There exists a need for a heterostructure light emitting device which may be fabricated from at least two wide bandgap semiconductor materials such as p-type zinc oxide-based materials, p-type beryllium zinc oxide alloy material, n-type gallium nitride-based materials, n-type indium gallium nitride, and n-type aluminum gallium nitride and having a p-type zinc oxide-based hole injection layer region deposited on a p-type gallium nitride-based cladding layer for the purpose of injecting hole carriers into a gallium nitride-based active layer region during device operation to increase the concentration of hole carriers in the active layer region during device operation for improved performance in function, device efficiency and light power output. The composition of the p-type zinc oxide-based hole injection layer can be selected to improve performance for efficiency and power in light emitting output of the device. Other layers can be formed in the light emitting device to improve performance.

There also exists a need for a heterostructure light emitting device which may be fabricated from at least two wide bandgap semiconductor materials such as p-type zinc oxide-based materials, p-type beryllium zinc oxide alloy material, n-type gallium nitride-based materials, n-type indium gallium nitride, and n-type aluminum gallium nitride and having a p-type zinc oxide-based hole injection layer region deposited on a p-type gallium nitride based cladding layer for the purpose of injecting hole carriers into a gallium nitride-based active layer region during device operation to increase the concentration of hole carriers in the active layer region during device operation, and with such device having an ohmic contact layer region deposited on the p-type zinc oxide-base hole injection layer region for improved performance in function, device efficiency and light power output. The composition of the p-type zinc oxide-based hole injection layer can be selected to improve performance for efficiency and power in light emitting output of the device. The ohmic contact layer region may comprise a layer, or more than one layer, selected from the list including, but not limited to, indium tin oxide, gallium zinc oxide, and indium zinc oxide. Other layers can be formed in the light emitting device to improve performance.

### SUMMARY OF THE INVENTION

The present invention addresses these needs, among other aspects. In one embodiment, the invention provides a layered heterostructure for improvement in function and efficiency for light emitting devices, and with particular capabilities for operation at high efficiencies and at high powers.

One embodiment of the invention provides a heterostructure light emitting device comprising a gallium nitride-based and zinc oxide-based semiconductor layered structure comprising at least a substrate, a gallium nitride-based n-cladding layer region, a gallium nitrite-based active layer region, a gallium nitride-based p-cladding layer, a p-type zinc oxide-based layer region, and an ohmic contact layer. Electrical leads are formed to n-electrode and p-electrode pads. The device formed is a light emitting device.

One embodiment of a layered heterostructure light emitting device in accordance with the invention employs semiconductor layered regions comprising a multiplicity of semiconductor materials. As one example of a light emitting device, a p-type zinc oxide-based semiconductor layer region provides a source of p-type carriers (holes) in sufficient proximity to a gallium nitride-based active layer region of the device that the concentration of p-type (hole) carriers in the gallium nitride-based active layer region is increased during device operation, thereby increasing the efficiency and power performance of the device.

In one embodiment of the invention, a p-type zinc oxide-based semiconductor layered region located on a p-type gallium nitride-base cladding layer region formed on a gallium nitride-based active layer region is the source of hole carriers that can be injected into the gallium nitride-based active layer region during device operation, thereby increasing the efficiency and power performance of the light emitting device. As such, the p-type zinc oxide-based semiconductor layer region has the function of a hole injection source layer region. In one embodiment, the p-type zinc oxide-based semiconductor layer region is formed to a thickness between about 0.1 nm to 2000 nm.

In one embodiment of the invention, the indium tin oxide layer is used as the ohmic contact layer, thereby increasing the efficiency and power performance of the device. As such, the p-type zinc oxide-based semiconductor layer region is not the ohmic contact layer region. The ohmic contact layer region is formed to a thickness between about 0.1 nm to 2000 nm.

In one embodiment of the present invention, the device may also include a buried insertion layer formed and located between the p-type zinc oxide-based hole injection layer region and the ohmic contact layer region to improve ohmic contact, with the composition of the insertion layer comprised of one, or more than one, element selected from the listing including, but not limited to, Ni, Au, Pt, Pd, Mg, Cu, Zn, Ag, Sc, Co, Rh, Li, Be, Ca, Ru, Re, Ti, Ta, Na, and La. The insertion layer is formed to a thickness between about 0.1 nm to 100 nm.

In one embodiment of the present invention, the device may also include a buried insertion layer formed and located on the ohmic contact layer region to improve ohmic contact, with the composition of the insertion layer comprised of one, or more than one, element selected from the listing including, but not limited to, Ni, Au, Pt, Pd, Mg, Cu, Zn, Ag, Sc, Co, Rh, Li, Be, Ca, Ru, Re, Ti, Ta, Na, and La. The insertion layer is formed to a thickness between about 0.1 nm to 100 nm.

The composition of the p-type zinc oxide-based hole injection layer region can be selected to improve performance for efficiency and light power output of the device.

Without limiting the scope of the present invention, other embodiments, examples, practices or aspects of the invention may employ or provide one or more of the following:

1) Beryllium, zinc, and oxygen alloys (BeZnO alloys) employed as a p-type zinc oxide-based semiconductor layer region.

2) Beryllium, magnesium, zinc, and oxygen alloys (BeMgZnO alloys) employed as a p-type zinc oxide-based semiconductor layer region.

3) (Group II elements, zinc, and oxygen) alloys employed as a semiconductor layer region.

4) BeMgZnO alloys employed as a p-type zinc oxide-based semiconductor layer region wherein magnesium can be used to improve lattice matching between adjacent layers.

5) Zinc, cadmium, selenium, sulfur, and oxygen alloys (ZnCdSeSO alloys) employed as a p-type zinc oxide-based semiconductor layer region.

6) Zinc, cadmium, selenium, sulfur, beryllium, and oxygen alloys (BeZnCdSeSO alloys) employed as a p-type zinc oxide-based semiconductor layer region wherein beryllium can be used to improve lattice matching between adjacent layers.

7) The ohmic contact layer region may cover all or a portion of the p-type zinc oxide-based semiconductor layer region.

8) Layers may be grown epitaxially to improve device performance.

These and other embodiments, examples, practices and aspects of the present invention are described in detail below and in conjunction with the attached drawing figures, as are methods of fabricating the noted structures. In particular, other details, advantages and features of the invention, and the manner in which operation of light emitting devices in accordance with the invention can be carried out will become more apparent to one skilled in the art from the following detailed description of the invention, in conjunction with the accompanying drawings that illustrate exemplary embodiments of the invention.

### BRIEF DESCRIPTION OF THE DRAWINGS

FIG. 1 is a schematic diagram illustrating one embodiment of a light emitting device in accordance with the present invention comprising a substrate, a buffer layer, an n-type gallium nitride-based semiconductor cladding layer region, a gallium nitride-based active layer region, a p-type gallium nitride-based cladding layer region, a p-type zinc oxide-based hole injection layer region, an indium tin oxide ohmic contact layer region, a p-electrode, and an n-electrode.

FIG. 2 is a schematic diagram illustrating another embodiment of the present invention comprising a substrate, a buffer layer, an n-type gallium nitride-based semiconductor cladding layer region, a gallium nitride-based active layer region, a p-type gallium nitride-based cladding layer region, a p-type zinc oxide-based hole injection layer region, an indium tin oxide ohmic contact layer region, a reflective layer region, a protective capping layer region, a p-electrode, and an n-electrode.

### DETAILED DESCRIPTION OF THE INVENTION

### Overview:

The present invention makes use of and implements the following realizations by the inventors:

1) The overall operating efficiency for a light emitting device comprising inorganic wide bandgap materials that are gallium nitride-based, such as gallium nitride (GaN), indium gallium nitride (InGaN), aluminum gallium nitride (AlGaN) and indium aluminum gallium nitride (InAlGaN), can be improved if the concentration of p-type carriers (holes) in the active layer region can be increased.

2) Furthermore, a higher concentration of p-type carriers (holes) can be obtained by using semiconductor materials that are zinc oxide-based, such as zinc oxide (ZnO), than can be obtained in semiconductor materials that are gallium nitride-based, such as gallium nitride (GaN), indium gallium nitride (InGaN), aluminum gallium nitride (AlGaN), and indium aluminum gallium nitride (InAlGaN).

3) The overall operating efficiency for a light emitting device comprising inorganic wide bandgap materials that are gallium nitride-based, such as gallium nitride (GaN), indium gallium nitride (InGaN), aluminum gallium nitride (AlGaN) and indium aluminum gallium nitride (InAlGaN), would be improved if the concentration of p-type carriers (holes) in the active layer region were increased by formation of at least one p-type semiconductor layer region located in close proximity to the gallium nitride-based active layer region, wherein the p-type semiconductor layer region could provide p-type carriers (holes) to the gallium nitride-based active layer region during device operation.

4) The overall operating efficiency for a light emitting device comprised of inorganic wide bandgap materials that are gallium nitride-based, such as gallium nitride (GaN), indium gallium nitride (InGaN), aluminum gallium nitride (AlGaN) and, indium aluminum gallium nitride (InAlGaN), would be improved if the concentration of p-type carriers (holes) in the active layer region were increased by formation of at least one p-type zinc oxide-based semiconductor layer region located in close proximity to the gallium nitride-based active layer region, wherein the p-type zinc oxide-based layer region could provide p-type carriers (holes) to the gallium nitride-based active layer region during device operation.

5) The overall operating efficiency for a light emitting device comprised of inorganic wide bandgap materials that are gallium nitride-based, such as gallium nitride (GaN), indium gallium nitride (InGaN), aluminum gallium nitride (AlGaN) and indium aluminum gallium nitride (InAlGaN), would be improved if the concentration of p-type carriers (holes) in the active layer region were increased by formation of at least one p-type zinc oxide-based semiconductor layer region located in close proximity to the gallium nitride-based active layer region, wherein the p-type zinc oxide-based layer region could inject p-type carriers (holes) to the gallium nitride-based active layer region during device operation.

6) The overall operating efficiency for a light emitting device comprised of inorganic wide bandgap materials that are gallium nitride-based, such as gallium nitride (GaN), indium gallium nitride (InGaN), aluminum gallium nitride (AlGaN) and indium aluminum gallium nitride (InAlGaN), would be improved if the concentration of p-type carriers (holes) in the active layer region were increased by formation of at least one p-type zinc oxide-based semiconductor layer region located in close proximity to the gallium nitride-based active layer region and with such p-type zinc oxide-based layer region having p-type carrier (hole) concentration higher than that of the gallium nitride-based active layer region, wherein the p-type zinc oxide-based layer region could inject p-type carriers (holes) to the gallium nitride-based active layer region during device operation.

7) Furthermore, the overall operating efficiency for a light emitting device can be improved by increasing the concentration of p-type carriers in the active layer region and by decreasing electrical contact resistance of the device.

8) A semiconductor light emitting device has a layered structure. As such, the structure and electrical properties of certain layers and layer regions within the device can improve the overall operating characteristics, efficiency, performance, and uses of the device. Likewise, the material composition of the semiconductor material used to form the layers and layer regions within the device can critically affect the overall operating characteristics, efficiency, performance, and uses of the device.

9) The overall operating efficiency for a light emitting device can be improved by use of a heterostructure that provides an increase in the hole concentration in the active layer region of the device. A heterostructure device containing a p-type layer region comprised of a semiconductor material that is a source of hole carriers to the active layer region comprising a different semiconductor material during device operation can improve the overall operating characteristics, efficiency, performance, and uses of the device.

10) A heterostructure device containing a p-type layer region comprised of a wide bandgap semiconductor material that is a source of hole carriers to an active layer region comprising a different wide bandgap semiconductor material during device operation can improve the overall operating characteristics, efficiency, performance, and uses of the device.

11) A heterostructure device containing a p-type layer region comprised of a wide bandgap semiconductor material that injects hole carriers into an active layer region comprising of a different wide bandgap semiconductor material during device operation can improve the overall operating characteristics, efficiency, performance, and uses of the device.

12) A heterostructure device containing a p-type layer region comprised of a wide bandgap semiconductor of a first type-based material formed on a p-type cladding layer region comprising a wide bandgap semiconductor of a second type-based material, wherein the p-type layer region of the first type-based material is a source of hole carriers for an active layer region of second type-based material during device operation can improve the overall operating characteristics, efficiency, performance, and uses of the device.

13) A heterostructure device containing a p-type layer region comprised of a wide bandgap semiconductor material of a first composition-type formed on a p-type cladding layer region comprising a wide bandgap semiconductor material of a second composition-type, wherein the p-type layer region of the material of the first composition-type injects hole carriers into an active layer region of the material of the second composition-type during device operation can improve the overall operating characteristics, efficiency, performance, and uses of the device.

14) A heterostructure device containing a p-type layer region comprised of a wide bandgap semiconductor material that is a source of hole carriers for an active layer region comprising of a different wide bandgap semiconductor material during device operation, and such device containing an ohmic contact layer formed on the p-type hole injecting layer region can improve the overall operating characteristics, efficiency, performance, and uses of the device.

15) A heterostructure device containing a p-type layer region comprised of a wide bandgap semiconductor material that injects hole carriers into an active layer region comprising of a wide bandgap semiconductor material of different composition during device operation, and such device containing an ohmic contact layer formed on the p-type hole injecting layer region can improve the overall operating characteristics, efficiency, performance, and uses of the device.

16) A heterostructure device containing a p-type layer region comprised of a wide bandgap semiconductor of a first composition type-based material formed on a p-type cladding layer region comprising a wide bandgap semiconductor of a second composition type-based material, wherein the p-type layer region of the first composition type-based material is a source of hole carriers to an active layer region of second composition type-based material during device operation, and such device containing an ohmic contact layer formed on the p-type hole source layer region can improve the overall operating characteristics, efficiency, performance, and uses of the device.

17) A heterostructure device containing a p-type layer region comprised of a wide bandgap semiconductor of a first composition type-based material formed on a p-type cladding layer region comprising a wide bandgap semiconductor of a second composition type-based material, wherein the p-type layer region of the first composition type-based material injects hole carriers into an active layer region of second composition type-based material during device operation, and such device containing an ohmic contact layer formed on the p-type hole injecting layer region can improve the overall operating characteristics, efficiency, performance, and uses of the device.

### Illustrated Embodiments/Practices of the Invention:

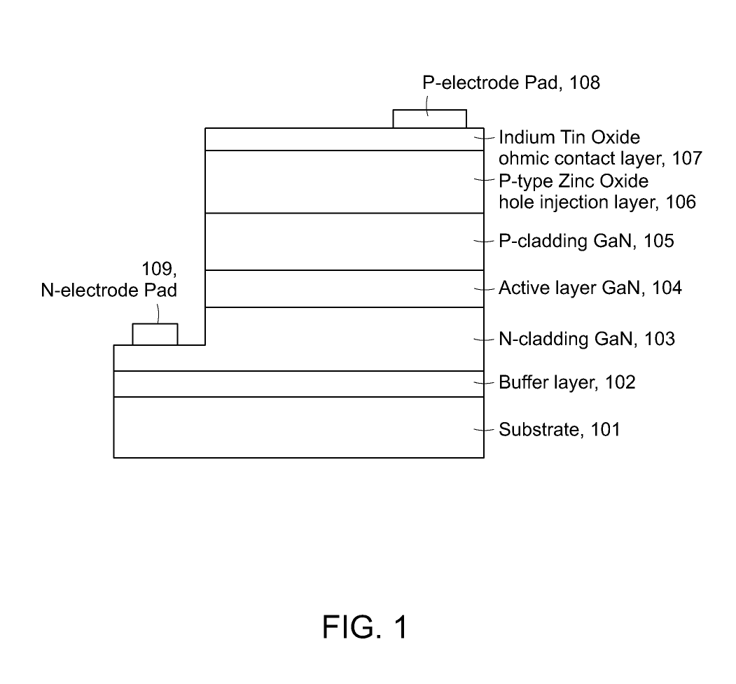

Referring now to FIG. 1, there is shown a schematic diagram of one embodiment of a light emitting device in accordance with the present invention. In particular, FIG. 1 is cross-section view that illustrates the layered structure of a light emitting device in accordance with the invention.

As indicated in FIG. 1, in one embodiment of the invention, a buffer layer 102 is grown on a substrate 101. An n-type cladding layer region 103 of gallium nitride-based semiconductor material is grown on the buffer layer. A gallium nitride-based active layer region 104 is grown on the n-type gallium nitride-based cladding layer region. A p-type cladding layer region 105 of gallium nitride-based semiconductor material is grown on the gallium nitride-based active layer region. A p-type hole injection layer region 106 of zinc oxide-based semiconductor material is grown on the p-type gallium nitride-based cladding layer region. An ohmic contact layer region 107 comprised of a layer of indium tin oxide is deposited on the p-type zinc oxide-based hole injection layer region. A p-electrode pad 108 is formed on the ohmic contact layer. The layered structure is etched to form an area on the n-cladding gallium nitride-based layer region suitable for formation of an n-electrode pad, and an n-electrode pad 109 is formed on such area. The device may also include (not shown) a buried insertion layer formed and located between the p-type zinc oxide layer hole injection region and the ohmic contact layer region, wherein the buried insertion layer is comprised of one, or more than one, element selected from the listing including, but not limited to, Ni, Au, Pt, Pd, Mg, Cu, Zn, Ag, Sc, Co, Rh, Li, Be, Ca, Ru, Re, Ti, Ta, Na, and La. The p-type zinc oxide based semiconductor layer is formed to a thickness between about 0.1 nm to 2000 nm. The indium tin oxide layer is formed to a thickness between about 0.1 nm to 2000 nm. If a buried insertion layer is formed, its thickness is between about 0.1 nm to 100 nm.

The material composition of the p-type zinc oxide-based hole injection layer region can be selected to improve performance for efficiency and light power output of the device.

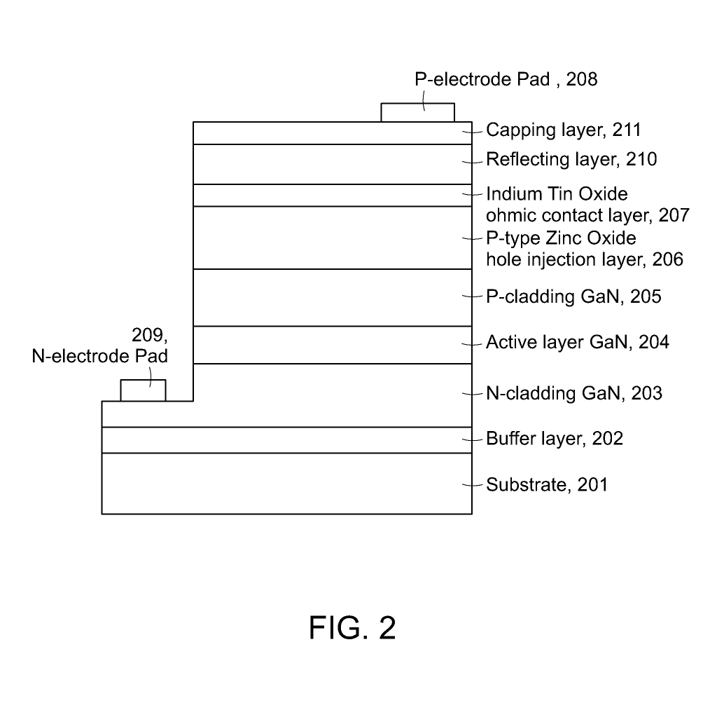

FIG. 2 is a schematic diagram of another embodiment of a light emitting device in accordance with the present invention. In particular, FIG. 2 is cross-section view that illustrates the layered structure of a light emitting device in accordance with the invention.

As indicated in FIG. 2, in one embodiment of the invention, a buffer layer 202 is grown on a single crystal substrate 201. An n-type cladding layer region 203 of gallium nitride-based semiconductor material is grown on the buffer layer. A gallium nitride-based active layer region 204 is grown on the n-type cladding layer region. A p-type cladding layer region 205 of gallium nitride-based semiconductor material is grown on the gallium nitride-based active layer region. A p-type hole injection layer region 206 of zinc oxide-based semiconductor material is grown on the p-type gallium nitride-based cladding layer region. An ohmic contact layer region 207 comprised of a layer of indium tin oxide is deposited on the p-type zinc oxide-based hole injection layer region. A reflective layer region 210 is formed on the ohmic contact layer region using one, or more than one, element selected from the list including, but not limited to Ag, Al, Zn, Mg, Ru, Ti, Rh, Cr, and Pt with such reflective layer useful for extraction of light when the device is used in a flip-chip light emitting device design. A protective capping layer region 211 is formed on the reflective layer region using one, or more than one, element or compound from the list including, but not limited to Ni, Pt, Pd, Zn, and TiN, with such protective capping layer region useful for improving electrical contact to the p-electrode and for suppressing oxidation of the reflective layer region to improve device lifetime. A p-electrode pad 208 is formed on the protective capping layer region. The layered structure is etched to form an area on the n-cladding layer region suitable for formation of an n-electrode pad, and an n-electrode pad 209 is formed on such area. The device may also include (not shown, but readily understood by one skilled in the art in connection with the entirety of this patent application) a buried insertion layer formed and located between the p-type zinc oxide-based layer region and the ohmic contact layer region, wherein the buried insertion layer is comprised of one, or more than one, element selected from the listing including, but not limited to, Ni, Au, Pt, Pd, Mg, Cu, Zn, Ag, Sc, Co, Rh, Li, Be, Ca, Ru, Re, Ti, Ta, Na, and La. The p-type zinc oxide-based semiconductor layer region is formed to a thickness between about 0.1 nm to 2000 nm. The ohmic contact layer region is formed to a thickness between about 0.1 nm to 2000 nm. The reflective layer region is formed to a thickness between about 0.1 nm to 2000 nm. The protective capping layer region is formed to a thickness between about 0.1 nm to 2000 nm. If a buried insertion layer is formed, its thickness is between about 0.1 nm to 100 nm.

The material composition of the p-type zinc oxide-based hole injection layer region can be selected to improve performance for efficiency and light power output of the device.

Techniques of growing layers, applying electrical leads, and forming electrical contacts, for example, may include techniques known in the art, or techniques described in patent applications of one or more of the inventors named in the present application for patent, including those listed above; and which other applications are incorporated by reference herein.

### Additional Light Emitting Device Examples

Many other embodiments, examples and variations of the present invention are possible, and are within the spirit and scope of the invention as defined in the claims set forth below. By way of further example, in another light emitting embodiment of the invention, using a layered structure like that shown in FIG. 1, a p-type hole injection layer region of beryllium zinc oxide semiconductor alloy region is grown on the p-type gallium nitride-based cladding layer region. An ohmic contact layer region comprised of a layer of indium tin oxide is deposited on the p-type beryllium zinc oxide hole injection layer region. A p-electrode pad is formed on the ohmic contact layer region. The layered structure is etched to form an area on the n-cladding layer region suitable for formation of an n-electrode pad, and an n-electrode pad is formed on such area. The device may also include (not shown) a buried insertion layer formed and located between the p-type zinc beryllium zinc oxide layer region and the ohmic contact layer region, wherein the buried insertion layer is comprised of one, or more than one, element selected from the listing including, but not limited to, Ni, Au, Pt, Pd, Mg, Cu, Zn, Ag, Sc, Co, Rh, Li, Be, Ca, Ru, Re, Ti, Ta, Na, and La. The device formed is a light emitting diode. The p-type beryllium zinc oxide semiconductor layer is formed to a thickness between about 0.1 nm to 2000 nm. The indium tin oxide layer is formed to a thickness between about 0.1 nm to 2000 nm. The reflective layer region is formed to a thickness between about 0.1 nm to 2000 nm. The protective capping layer region is formed to a thickness between about 0.1 nm to 2000 nm. If a buried insertion layer is formed, its thickness is between about 0.1 nm to 100 nm.

By way of another further example, in a light emitting embodiment of the invention, using a layered structure like that shown in FIG. 2, a p-type hole injection layer region of beryllium zinc oxide semiconductor alloy is grown on the p-type gallium nitride-based cladding layer region. An ohmic contact layer region comprised of a layer of indium tin oxide is deposited on the p-type zinc oxide-based hole injection layer region. A reflective layer region is formed on the ohmic contact layer region using one, or more than one, element selected from the list including, but not limited to Ag, Al, Zn, Mg, Ru, Ti, Rh, Cr, and Pt with such reflection layer region useful for extraction of light when the device is used in a flip-chip light emitting device design. A protective capping layer region is formed on the reflective layer region using one, or more than one, element or compound from the list including, but not limited to Ni, Pt, Pd, Zn, and TiN, with such protective capping layer useful for improving electrical contact to the p-electrode and for suppressing oxidation of the reflective layer region to improve device lifetime. A p-electrode pad is formed on the protective capping layer region. The layered structure is etched to form an area on the n-cladding layer region suitable for formation of an n-electrode pad, and an n-electrode pad is formed on such area. The p-type beryllium zinc oxide semiconductor layer is formed to a thickness between about 0.1 nm to 2000 nm. The indium tin oxide layer is formed to a thickness between about 0.1 nm to 2000 nm. The reflective layer region is formed to a thickness between about 0.1 nm to 2000 nm. The protective capping layer region is formed to a thickness between about 0.1 nm to 2000 nm. If a buried insertion layer is formed, its thickness is between about 0.1 nm to 100 nm. The device may also include (not shown) an insertion layer formed and located between the p-type zinc oxide-based layer region and the ohmic contact layer region, wherein the buried insertion layer is comprised of one, or more than one, element selected from the listing including, but not limited to, Ni, Au, Pt, Pd, Mg, Cu, Zn, Ag, Sc, Co, Rh, Li, Be, Ca, Ru, Re, Ti, Ta, Na, and La. The device formed is a light emitting diode. The device may also include (not shown) an insertion layer formed on the ohmic contact layer region, wherein the buried insertion layer is comprised of one, or more than one, element selected from the listing including, but not limited to, Ni, Au, Pt, Pd, Mg, Cu, Zn, Ag, Sc, Co, Rh, Li, Be, Ca, Ru, Re, Ti, Ta, Na, and La. The device formed is a light emitting diode.

By way of other examples of the present invention, a light emitting embodiment of the invention, using a layered structure, is fabricated that employs a p-type zinc oxide-based semiconductor layer region formed in proximity to a gallium nitride-based active layer region of a gallium nitride-based device, whereby holes from the p-type zinc oxide-based layer region are injected into the gallium nitride-based active layer region. The device formed is a light emitting diode. The composition of the p-type zinc oxide-based hole injection layer region can be selected to improve performance for efficiency and light power output of the device.

By way of other examples, in other light emitting embodiment of the invention, using a layered structure that employs a p-type zinc oxide-based semiconductor layer region formed in proximity to a gallium nitride-based active layer region of a gallium nitride-based device, whereby holes from the p-type zinc oxide-based layer region are injected into the gallium nitride-based active layer region for which one, or more than one, of the layered regions is comprised of a single layer. The device formed is a light emitting diode.

By way of other examples, in other light emitting embodiment of the invention, using a layered structure that employs a p-type zinc oxide-based semiconductor layer region formed in proximity to a gallium nitride-based active layer region of a gallium nitride-based device, whereby holes from the p-type zinc oxide-based layer region are injected into the gallium nitride-based active layer region for which the device may also include a buried insertion layer formed and located between the p-type zinc oxide-based layer region and the ohmic contact layer, wherein the buried insertion layer is comprised of one, or more than one, element selected from the listing including, but not limited to, Ni, Au, Pt, Pd, Mg, Cu, Zn, Ag, Sc, Co, Rh, Li, Be, Ca, Ru, Re, Ti, Ta, Na, and La. The device formed is a light emitting diode.

By way of still other examples, embodiments and practices of the present invention:

1) The p-type zinc oxide-based semiconductor hole injection layer region can be comprised of one, or more than one, layer of material selected from the list including, but not limited to, BeZnO, MgZnO, BeMgO, and BeMgZnO alloy material.

2) The p-type zinc oxide-based semiconductor hole injection layer region can be comprised of one, or more than one, layer of material selected from the list including, but not limited to, ZnCdSeO, ZnCdSO, ZnCdSSeO, ZnSSeO, ZnSO, and ZnSeO alloy material.

3) The p-type zinc oxide-based semiconductor hole injection layer region can be comprised of one, or more than one, layer of material selected from the list including, but not limited to, BeZnO, MgZnO, BeMgO, and BeMgZnO, ZnCdSeO, ZnCdSO, ZnCdSSeO, ZnSSeO, ZnSO, and ZnSeO alloy material with incorporation of one or more elements such as Mg or Be for improvement of lattice matching to one or more other layers.

4) The structure can be prepared such that the dopant for the p-type zinc oxide-based semiconductor hole injection layer is at least one element selected from the group 1, 11, 5 and 15 elements.

5) The structure can be prepared such that the dopant for the p-type zinc oxide-based semiconductor hole injection layer region is selected from the group consisting of arsenic, phosphorus, antimony and nitrogen; or, in a particular aspect of the invention, the dopant for the p-type zinc oxide semiconductor layer region may be arsenic alone.

6) Alternatively, the structure can be prepared such that the dopant for the p-type zinc oxide-based semiconductor hole injection layer is at least one element selected from the group 1, 11, 5 and 15 elements; or an element, or more than one element, selected from the group consisting of arsenic, phosphorus, antimony and nitrogen; or in one example, arsenic alone.

7) The structure can be prepared such that the dopant for the p-type beryllium zinc oxide alloy semiconductor hole injection layer region is at least one element selected from the group 1, 11, 5 and 15 elements.

8) The structure can be prepared such that the dopant for the p-type beryllium zinc oxide alloy semiconductor hole injection layer region is selected from the group consisting of arsenic, phosphorus, antimony and nitrogen; or, in a particular aspect of the invention, the dopant for the p-type zinc oxide semiconductor layer region may be arsenic alone.

9) Alternatively, the structure can be prepared such that the dopant for the p-type beryllium zinc oxide alloy hole injection layer region is at least one element selected from the group 1, 11, 5 and 15 elements; or at least one element selected from the group consisting of arsenic, phosphorus, antimony and nitrogen; or particularly, arsenic alone.

10) Alternatively, the structure can be prepared such that the dopant for the p-type zinc oxide-based semiconductor hole injection layer region can be incorporated during growth.

11) Alternatively, the structure can be prepared such that the dopant for the p-type zinc oxide-based semiconductor hole injection layer region can be incorporated by process methods selected from the list including, but not limited to, hybrid beam deposition, thermal flux, element flux, plasma flux, diffusion, thermal diffusion, sputtering, and/or ion implantation.

12) Alternatively, the structure can be prepared such that the ohmic contact layer region can be formed by process methods selected from the listing including, but not limited to, hybrid beam deposition, thermal flux, element flux, plasma flux, diffusion, thermal diffusion, sputtering, and/or ion implantation.

13) Alternatively, the composition of the p-type zinc oxide-based hole injection layer region can be selected to improve performance for efficiency and light power output of the device.

14) Alternatively, the structure can be prepared such that the ohmic contact layer region is one, or more than one, layer and selected from the listing including, but not limited to, indium tin oxide, gallium zinc oxide, and indium zinc oxide. The ohmic contact layer region is formed to a thickness between about 0.1 nm to 2000 nm.

15) Alternatively, the structure can be prepared such that the p-type zinc oxide-based semiconductor hole injection layer region can be formed by process methods selected from the list including, but not limited to, hybrid beam deposition, thermal flux, element flux, plasma flux, diffusion, thermal diffusion, sputtering, and/or ion implantation.

16) Alternatively, the structure can be prepared such that the ohmic contact layer region can be formed by process methods selected from the list including, but not limited to, hybrid beam deposition, thermal flux, element flux, plasma flux, diffusion, thermal diffusion, sputtering, and/or ion implantation.

17) Alternatively, the structure can be prepared wherein the p-type zinc oxide-based hole injection layer region is an oxide material selected from the list including, but not limit to, an oxide comprised of a Group II element, ZnO, BeZnO, MgZnO, BeMgZnO, ZnCdSeO, ZnCdSO, ZnCdSSeO, ZnSSeO, ZnSO, and ZnSeO. The p-type zinc oxide-based layer region is formed to a thickness between about 0.1 nm to 2000 nm.

18) Alternatively, the structure can be prepared wherein the p-type zinc oxide-based hole injection layer region is an oxide material selected from the list including, but not limit to, an oxide comprised of a Group II element, ZnO, MgZnO, ZnCdSeO, ZnCdSO, ZnCdSSeO, ZnSSeO, ZnSO, and ZnSeO with Be added for improvement of lattice matching between layers. The p-type zinc oxide-based layer region is formed to a thickness between about 0.1 nm to 2000 nm.

19) Alternatively, the structure can be prepared wherein the p-type zinc oxide-based hole injection layer region is an oxide material selected from the list including, but not limit to, an oxide comprised of a Group II element, ZnO, and BeZnO with Mg added for improvement of lattice matching between layers. The p-type zinc oxide-based layer region is formed to a thickness between about 0.1 nm to 2000 nm.

The invention and its technical advantages will be still further illustrated and understood through the following additional examples.

### Further Examples and Description of the Invention:

The following discussion provides still further description of various embodiments and examples of the present invention and their characteristics. As noted above, the present invention relates to a layered heterostructure light emitting device for improvements in performance of light emitting devices, and particularly their high efficiency and high power performance.

Although a particular embodiment is next described with respect to a light emitting device that is a LED, it will be understood that the present invention may be practiced with respect to other types of light emitting devices, such as, for example, a laser diode (LD) and other devices and configurations as listed elsewhere in this document.

In one embodiment of this invention, a wafer with a layered structure comprising a sapphire substrate, a buffer layer, an n-type gallium nitride-based cladding layer region, a gallium nitride-based active layer region, and a p-type gallium nitride-based cladding layer region was placed in a hybrid beam deposition reactor, and heated to approximately 650° C. The pressure was reduced to approximately 1×10⁻⁵ torr and the p-type gallium nitride-based cladding layer cleaned with RF oxygen plasma for 30 minutes. The temperature was then lowered to 550° C., and then a layer of zinc oxide semiconductor material p-type doped with arsenic (As) was deposited to a thickness of approximately 0.3 microns on the p-type gallium nitride-based cladding layer region. Then the temperature was lowered to room temperature. A layer comprising indium tin oxide was deposited to a thickness of approximately 1000 nm on the p-type zinc oxide semiconductor layer by a sputtering method.

(A more detailed description of one or more exemplary process(es) useful for depositing a zinc oxide layer, and in particular a p-type zinc oxide layer doped with arsenic and other materials (which may include, for example, beryllium zinc oxide) is set forth, by way of example, in U.S. Pat. Nos. 6,475,825 (White et al.) and 6,610,141 (White et al.), and PCT Patent Application Nos. PCT/US03/27143 (Ryu et al.)), PCT/US05/043821 (Ryu et al.) and PCT/US06/011619 (Ryu el al.), each of which is incorporated herein by reference, and made a part of this application, as if set forth in its entirety.

The wafer with deposited layers was patterned and etched and electrode pads formed on the n-type gallium nitride-based layer region and on the indium tin oxide layer. The ohmic contact to the n-type gallium nitride-based layer region was formed using Cr and Au metals. The ohmic contact to the indium tin oxide ohmic contact layer was formed using Cr and Au metals.

A voltage difference was applied to the electrodes and the current-voltage (I-V) characteristics of the device were measured. Light emission from the device under forward bias conditions was measured to obtain power and efficiency for the light emitting device.

Those skilled in the art will readily appreciate that among other variations, one could fabricate a device with layered structures different than that used in the embodiment described above. The composition of the p-type zinc oxide-based hole injection layer region can be selected to improve performance for efficiency and light power output of the device.

### Conclusion

A light emitting structure in accordance with the invention, having the disclosed layered structure, can be used to improve the performance, and in particular, its efficiency and output power. A light emitting device with a p-type zinc oxide-based hole injection layer region and an ohmic contact layer region in accordance with the invention would have many uses in high efficiency and high power device applications in photonic areas. Such uses could include, but would not be limited to, applications such as high efficiency white light sources, LEDs, LDs, and sensors for use in general and specialty lighting, displays, and spectroscopic studies.

Those skilled in the art will understand that they can also fabricate a light emitting device of the present invention, in accordance with the disclosure herein, with additional desirable features, such as a reflection layer region and a capping layer region for use in a flip-chip light emitting design.

The foregoing examples are set forth by way of illustration and not limitation. Similarly, the terms and expressions used herein are used as terms of description and not of limitation, and there is no intention in the use of such terms and expressions of excluding equivalents of the features shown and described, or portions thereof. Various additions, subtractions, and modifications are possible and are within the spirit and scope of the present invention. Moreover, any one or more features of any embodiment of the invention described herein or otherwise within the scope of the invention may be combined with any one or more other features of any other embodiment of the invention, without departing from the scope of the invention.

1. A heterostructure light emitting device with a layered structure comprising:
a substrate,
an n-type gallium nitride-based semiconductor cladding layer region,
a gallium nitride-based active layer region,
a p-type gallium nitride-based cladding layer region,
a p-type zinc oxide-based hole injection layer region, and
an ohmic contact layer region.

2. The heterostructure light emitting device of claim 1 further comprising:
a protective capping layer region.

3. The heterostructure light emitting device of claim 1 further comprising:
a reflective layer region; and
a protective capping layer region.

4. The device of claim 1, further comprising a buried insertion layer between the p-type zinc oxide-based hole injection layer region and the ohmic contact layer region, and wherein the buried insertion layer comprises at least one element selected from the list comprising Ni, Au, Pt, Pd, Mg, Cu, Zn, Ag, Sc, Co, Rh, Li, Be, Ca, Ru, Re, Ti, Ta, Na, and La.

5. The device of claim 2, further comprising a buried insertion layer between the ohmic contact layer region and the protective capping layer region, and wherein the buried insertion layer comprises at least one element selected from the list comprising Ni, Au, Pt, Pd, Mg, Cu, Zn, Ag, Sc, Co, Rh, Li, Be, Ca, Ru, Re, Ti, Ta, Na, and La.

6. The device of claim 3, further comprising a buried insertion layer between the ohmic contact layer region and the reflective layer region, and wherein the buried insertion layer comprises at least one element selected from the list comprising Ni, Au, Pt, Pd, Mg, Cu, Zn, Ag, Sc, Co, Rh, Li, Be, Ca, Ru, Re, Ti, Ta, Na, and La.

7. The light emitting device of claim 1, wherein the p-type zinc oxide-based hole injection layer region is an oxide material selected from the list comprising an oxide comprising a Group II element, ZnO, BeZnO, MgZnO, BeMgZnO, ZnCdSeO, ZnCdSO, ZnCdSSeO, ZnSSeO, ZnSO, and ZnSeO.

8. The light emitting device of claim 1, wherein the p-type zinc oxide-based hole injection layer region is an oxide material selected from the list comprising an oxide comprising a Group II element, ZnO, MgZnO, ZnCdSeO, ZnCdSO, ZnCdSSeO, ZnSSeO, ZnSO, and ZnSeO with Be added for improvement of lattice matching between layers.

9. The light emitting device of claim 1, wherein the p-type zinc oxide-based hole injection layer region is an oxide material selected from the list comprising an oxide comprising a Group II element, ZnO, and BcZnO with Mg added for improvement of lattice matching between layers.

10. The device of claim 1, wherein the p-type zinc oxide-based hole injection layer region is p-type zinc oxide material.

11. The device of claim 1, wherein the p-type zinc oxide-based hole injection layer region is p-type beryllium zinc oxide alloy material.

12. The light emitting device of claim 1, wherein the ohmic contact layer region comprises indium tin oxide.

13. The light emitting device of claim 1, wherein the ohmic contact layer region comprises gallium zinc oxide.

14. The light emitting device of claim 1, wherein the ohmic contact layer region comprises indium zinc oxide.

15. The light emitting device of claim 1, wherein the p-type zinc oxide-based hole injection layer region is at least a single layer.

16. The light emitting device of claim 1, wherein the dopant for the p-type zinc oxide-based hole injection layer region comprises at least one element selected from the group consisting of Group 1 (IA), Group 11 (IB), Group 5 (VB), and Group 15 (VA) elements.

17. The light emitting device of claim 1, wherein the dopant for the p-type zinc oxide-based hole injection layer region comprises at least one clement selected from the group consisting of nitrogen, arsenic, phosphorus, antimony and bismuth.

18. The light emitting device of claim 1, wherein the dopant for the p-type zinc oxide-based hole injection layer region comprises arsenic.

19. The light emitting device of claim 1, wherein the device contains a buffer layer formed on the substrate and located between the substrate and the n-type gallium nitride-based semiconductor cladding layer region.

20. The light emitting device of claim 1, wherein the p-type zinc oxide-based semiconductor layer region is formed to a thickness between about 0.1 nm to about 2000 nm and the ohmic contact layer region is formed to a thickness between about 0.1 nm to about 2000 nm.

21-22. (canceled)

23. A method of manufacturing a heterostructure light emitting device with a layered structure of claim 3, the method comprising:
forming an n-type gallium nitride-based semiconductor cladding layer region,
forming a gallium nitride-based active layer region on the n-type gallium nitride-based semiconductor cladding layer,
forming a p-type gallium nitride based cladding layer region on the gallium nitride-based active layer region,
forming a p-type zinc oxide-based hole injection layer region on the p-type gallium nitride based cladding layer region,
forming an ohmic contact layer on the p-type zinc oxide-based hole injection layer region,
forming a reflective layer on the ohmic contact layer region, and
forming a protective capping layer on the reflective layer region.

24. (canceled)
